(19) United States
(12) Patent Application Publication
(10) Pub. No.: US 2025/0151537 A1
(43) Pub. Date: May 8, 2025

(54) DISPLAY DEVICE AND METHOD OF FORMING THE SAME

(71) Applicant: LG Display Co., Ltd., Seoul (KR)

(72) Inventors: Yooji HWANG, Paju-si (KR); Yongmin KIM, Paju-si (KR); JungSun BAEK, Paju-si (KR)

(21) Appl. No.: 18/818,289

(22) Filed: Aug. 28, 2024

(30) Foreign Application Priority Data
Nov. 7, 2023 (KR) 10-2023-0152308

(51) Int. Cl. H10K 59/124; H10K 59/12; H10K 59/122; H10K 59/35

(52) U.S. Cl. CPC H10K 59/124; H10K 59/1201; H10K 59/122; H10K 59/353

(57) ABSTRACT

Embodiments of the disclosure relate to a display device and a method for manufacturing the same and may enhance the reliability of the display device by reducing the inflow path of harmful gases. The device includes an emission area and a non-emission area. The device includes a first and a second planarization layer. The second planarization layer includes a first opening in the emission area and a second opening in the non-emission area. The device includes an anode electrode on the second planarization layer, a light emitting layer, and a cathode electrode. The device includes a bank layer disposed in a portion of the emission area and at least a partial area on the first planarization layer and the second planarization layer in the non-emission area, and including at least one trench positioned in the second opening.

### CROSS-REFERENCE TO RELATED APPLICATION

This application claims priority from Korean Patent Application No. 10-2023-0152308, filed on Nov. 7, 2023, which is hereby incorporated by reference for all purposes as if fully set forth herein.

### BACKGROUND

### Technical Field

Embodiments of the disclosure relate to a display device and a method for manufacturing the same.

### Description of Related Art

As technology advances, display devices have been developed to produce higher quality images. In order for a display device to express a higher quality image, the image should be expressed with a greater number of pixels and, to that end, the display device requires more internal components, e.g., circuits or elements for emitting light. Accordingly, components within display devices have been downsized and integrated.

However, as the internal components are downsized and integrated, the display device may experience deterioration of reliability to a reduced inter-component gap, and deteriorate its optical characteristics with a higher chance of component-to-component interference.

### BRIEF SUMMARY

Embodiments of the disclosure may provide a display device with enhanced reliability and a method for manufacturing the same.

Embodiments of the disclosure may provide a display device and a method for manufacturing the same, which may enhance optical characteristics by minimizing inter-component interference in the display device.

Embodiments of the disclosure may provide a display device comprising a substrate where a plurality of subpixels including an emission area and a non-emission area are disposed, a first planarization layer on the substrate, a second planarization layer disposed on the first planarization layer and including a first opening positioned in the emission area and a second opening positioned in the non-emission area, an anode electrode disposed on the second planarization layer, a bank layer disposed in a portion of the emission area and at least a partial area on the first planarization layer and the second planarization layer in the non-emission area, and including at least one trench positioned in the second opening, a light emitting layer disposed on the anode electrode, and a cathode electrode disposed on the light emitting layer.

Embodiments of the disclosure may provide a display device comprising a substrate including an emission area and a transmissive area, a plurality of insulation layers on the substrate, a first planarization layer disposed on the plurality of insulation layers, a second planarization layer disposed on the first planarization layer and including a first opening positioned in the emission area and a second opening positioned between the emission area and the transmissive area, an anode electrode disposed on the second planarization layer, a bank layer disposed in a portion of the emission area and at least a partial area on the first planarization layer and the second planarization layer between the emission area and the transmissive area, a light emitting layer disposed on the anode electrode, and a cathode electrode disposed on the light emitting layer.

Embodiments of the disclosure may provide a method for manufacturing a display device, comprising forming a first planarization layer on a substrate, forming a second planarization layer so that a first opening is formed in an emission area and a second opening is formed in a non-emission area on the first planarization layer, forming an anode electrode on a portion of the second planarization layer, and forming a bank layer to have an opening in the emission area and a trench in the non-emission area.

According to embodiments of the disclosure, there may be provided a display device with enhanced reliability and a method for manufacturing the same.

According to embodiments of the disclosure, there may be provided display device and a method for manufacturing the same, which may enhance optical characteristics by minimizing inter-component interference in the display device.

According to embodiments of the disclosure, there may be provided a display device and a method for manufacturing the same, which may increase the efficiency of the display device by enhancing the reliability and optical characteristics of the display device and be thus capable of low power consumption.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view illustrating an example of a structure of a display device and a circuit structure included in a subpixel according to embodiments of the disclosure;

FIG. 2A is a view illustrating an example of a subpixel structure included in a display device according to embodiments of the disclosure;

FIG. 2B is a view illustrating an example of a line design structure corresponding to the subpixel structure of FIG. 2A;

FIG. 3 is a view illustrating an example of a cross-sectional structure of part I-I′ of FIG. 2B;

FIG. 4 is an enlarged view illustrating part A of FIG. 3;

FIG. 5 is a view illustrating another example of a subpixel structure included in a display device according to embodiments of the disclosure;

FIG. 6 is a view illustrating an example of a cross-sectional structure of part II-II′ of FIG. 5;

FIG. 7 is a view illustrating another example of a subpixel structure included in a display device according to embodiments of the disclosure;

FIG. 8 is a view illustrating an example of a cross-sectional structure of part III-III′ of FIG. 7;

FIG. 9 is a view illustrating another example of a cross-sectional structure of part III-III′ of FIG. 7; and

FIG. 10A, 10B, 10C, 10D, and 10E are views illustrating an example of a method for manufacturing a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

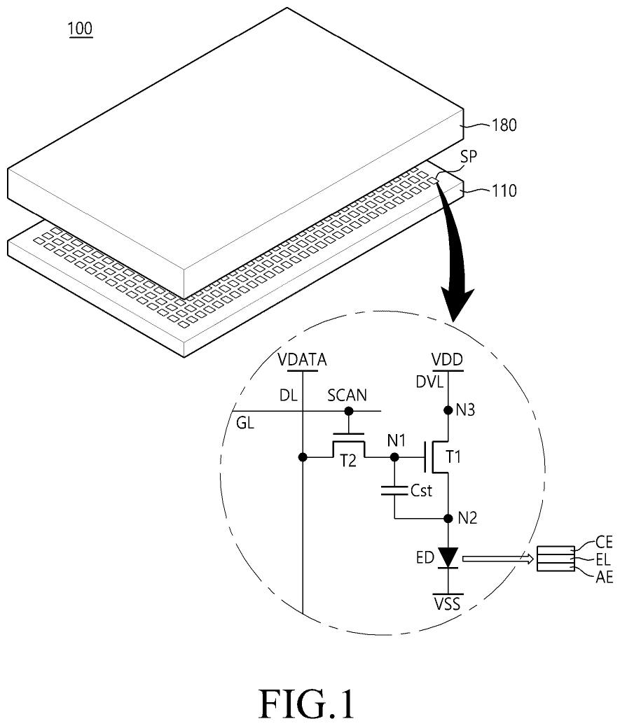

FIG. 1 is a view illustrating an example of a structure of a display device and a circuit structure included in a subpixel according to embodiments of the disclosure.

Referring to FIG. 1, a plurality of subpixels SP may be disposed in a display area of the display device 100.

Each of the plurality of subpixels SP may include a light emitting element ED and a subpixel circuit unit configured to drive the light emitting element ED.

The subpixel circuit unit may include a driving transistor T1 for driving the light emitting element ED, a scan transistor T2 for transferring the data voltage VDATA to the first node N1 of the driving transistor T1, and a storage capacitor Cst for maintaining a constant voltage during one frame.

The driving transistor T1 may include the first node N1 to which the data voltage may be applied, a second node N2 electrically connected with the light emitting element ED, and a third node N3 to which a driving voltage VDD is applied from a driving voltage line DVL. The first node N1 in the driving transistor T1 may be a gate node, the second node N2 may be a source node or a drain node, and the third node N3 may be the drain node or the source node. For convenience of description, described below is an example in which the first node N1 in the driving transistor T1 is a gate node, the second node N2 is a source node, and the third node N3 is a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor T1 of each subpixel SP. The cathode electrode CE may be a common electrode commonly disposed in the plurality of subpixels SP, and a base voltage VSS may be applied thereto.

Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

The light emitting element ED may have one or more predetermined emission areas.

The light emitting element ED may be an organic light emitting diode (OLED), an inorganic light emitting diode, or a quantum dot light emitting element. When the light emitting element ED is an organic light emitting diode, the light emitting layer EL of the light emitting element ED may include an organic light emitting layer EL including an organic material.

The scan transistor T2 may be on/off controlled by a scan signal SCAN, which is a gate signal, applied via the gate line GL and be electrically connected between the first node N1 of the driving transistor T1 and the data line DL.

The storage capacitor Cst may be electrically connected between the first node N1 and second node N2 of the driving transistor T1.

The subpixel circuit unit may have a 2 T (transistor) 1 C (capacitor) structure which includes two transistors DT and ST and one capacitor Cst and, in some cases, each subpixel SP may further include one or more transistors or one or more capacitors.

The capacitor Cst may be an external capacitor intentionally designed to be outside the driving transistor T1, but not a parasite capacitor (e.g., Cgs or Cgd) which is an internal capacitor that may be present between the first node N1 and the second node N2 of the driving transistor T1. Each of the driving transistor T1 and the scan transistor T2 may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer 180 may be disposed on the display panel 110 to prevent penetration of external moisture or oxygen into the circuit elements (particularly, the light emitting element ED). The encapsulation layer 180 may be disposed to cover the light emitting elements ED.

The subpixel SP may also be referred to as a pixel unit, and each of the plurality of subpixels SP may be disposed in a different form from that of FIG. 1 on the display panel 110 depending on the line structure.

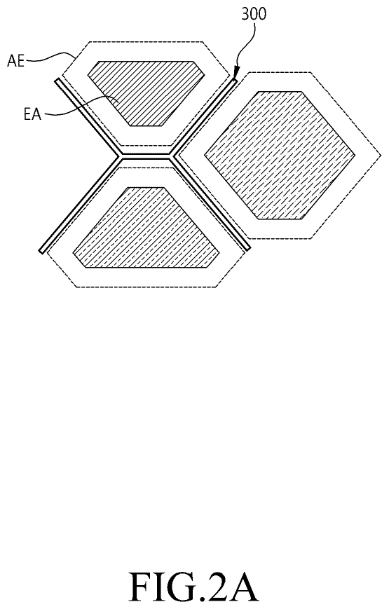

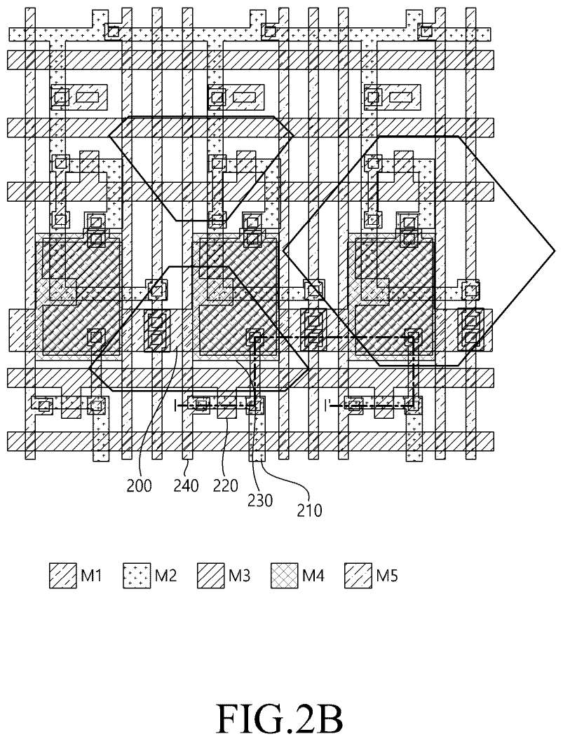

FIG. 2A is a view illustrating an example of a subpixel structure included in a display device according to embodiments of the disclosure.

Referring to FIGS. 1 and 2A, each of the plurality of subpixels SP may include a light emitting element ED that emits light of different colors. The plurality of subpixels SP may be divided into a first subpixel, a second subpixel, and a third subpixel according to the color of the light emitted by the light emitting element ED. For example, the first subpixel may include a light emitting element ED1 (not shown) that emits red light. The first subpixel may be referred to as a first pixel unit, the second subpixel may be referred to as a second pixel unit, and the third subpixel may be referred to as a third pixel unit.

The first subpixel, the second subpixel, and the third subpixel may be disposed adjacent to each other on the display panel 110.

Each subpixel SP may include an emission area EA, and the size and shape of the emission area EA of each subpixel SP may be different for each pixel.

A non-emission area in which no light is emitted may be present between the subpixels SP. The non-emission area may be an area other than the emission area EA in one subpixel SP.

The anode electrode AE may be disposed in an area wider than the emission area EA.

The reliability of the display device 100 may be enhanced according to the structure and area in which the anode electrode AE is disposed. The arrangement structure and area of the anode electrode AE are described below.

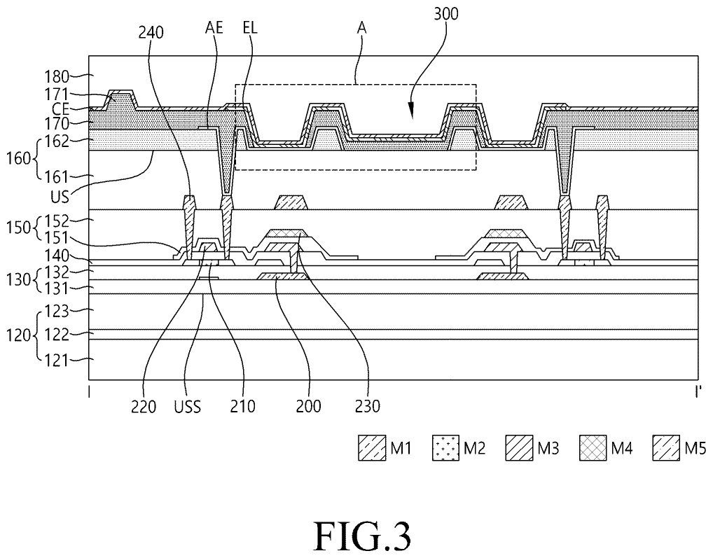

FIG. 2B is a view illustrating an example of a line design structure corresponding to the subpixel structure of FIG. 2A. FIG. 3 is a view illustrating an example of a cross-sectional structure of part I-I′ of FIG. 2B.

Referring to FIGS. 2B and 3, the substrate 120 may include a first substrate 121, an interlayer inorganic film 122 disposed on the first substrate 121, and a second substrate 123 disposed on the interlayer inorganic film 122.

The first substrate 121 and the second substrate 123 may be formed of a plastic material, e.g., polyimide.

The interlayer inorganic film 122 is for preventing moisture to penetrate into the substrate and may be formed of a single layer or multiple layers such as silicon oxide (SiOx). However, embodiments of the disclosure are not limited thereto.

A buffer layer 130 may be disposed on the substrate 120.

The buffer layer 130 may include a multi-buffer layer 131 and an active buffer layer 132 disposed on the multi-buffer layer 131. The buffer layer 130 may enhance adhesion between the layers formed on the buffer layer 130 and the substrate 120 and delay diffusion of moisture or oxygen penetrating into the substrate 120. The buffer layer 130 may be formed of a single layer of silicon nitride (SiNx) or silicon oxide (SiOx) or multiple layers thereof, but is not limited thereto.

A blocking layer 200 may be positioned between the multi-buffer layer 131 and the active buffer layer 132.

The blocking layer 200 may be disposed in a partial area on the multi-buffer layer 131, and there may be a plurality of blocking layers 200. For example, as illustrated in FIG. 3, the blocking layer 200 may be disposed in an area overlapping the capacitor electrode.

The blocking layer 200 may prevent the semiconductor pattern from malfunctioning by irradiating the semiconductor pattern with light incident from the outside of the display device 100.

Further, the blocking layer 200 may be formed of an opaque conductive material to block external light. For example, the blocking layer 200 may be formed of any one of molybdenum (Mo), copper (Cu), titanium (Ti), aluminum (Al), chromium (Cr), nickel (Ni), neodymium (Nd), tungsten (W), and gold (Au), or an alloy thereof.

In another subpixel SP of the same layer as the blocking layer 200, a layer playing the same role as the blocking layer 200 may be disposed using a first material layer M1.

The gate insulation layer 140 and the active layer 210 may be disposed on the buffer layer 130.

The gate insulation layer 140 is a layer for insulating the active layer 210 and the gate electrode 220 and may be disposed between the active layer 210 and the gate electrode 220.

The active layer 210 may be formed of a polycrystalline semiconductor material. For example, the polycrystalline semiconductor may be formed of low temperature poly silicon (LTPS) having high mobility.

A source area and a drain area conductorized by a doping process may be present on two opposite sides of the active layer 210. The source/drain area may refer to a portion of the active layer 210 connected to the source/drain electrode 240.

In another area of the same layer as the active layer 210, a layer playing the same role as the active layer 210 may be further disposed using a second material layer M2.

The gate electrode 220 and the interlayer insulation layer 150 may be disposed on the gate insulation layer 140.

The interlayer insulation layer 150 may include a first interlayer insulation layer 151 and a second interlayer insulation layer 152 disposed on the first interlayer insulation layer 151.

The interlayer insulation layer 150 may be formed of an insulating inorganic material such as silicon nitride (SiNx) or silicon oxide (SiOx), or may be formed of an insulating organic material.

The gate electrode 220 may be disposed between the first interlayer insulation layer 151 and the gate insulation layer 140.

The first capacitor electrode constituting the storage capacitor may be disposed on the same layer as the gate electrode 220, and the first capacitor electrode may be disposed using a third material layer M3.

The second capacitor electrode 230 may be disposed between the first interlayer insulation layer 151 and the second interlayer insulation layer 152. A layer playing the same role as the second capacitor electrode 230 may be disposed on the same layer as the second capacitor electrode 230 using a fourth material layer M4.

A source/drain electrode 240 may be disposed on the interlayer insulation layer 150. The source/drain electrode 240 may be formed through the interlayer insulation layer 150 and the gate insulation layer 140, and may be electrically connected to the source/drain area of the active layer 210.

Electrodes for wiring may be further disposed on the same layer as the source/drain electrode 240 using a fifth material layer M5.

A planarization layer 160 may be disposed on the interlayer insulation layer 150 and the source/drain electrode 240.

The planarization layer 160 may include a first planarization layer 161 and a second planarization layer 162 disposed on the first planarization layer 161.

The planarization layer 160 may protect the thin film transistor disposed below and may alleviate or planarize a step due to various patterns.

The planarization layer 160 may be formed of at least one of organic insulating materials such as, but not limited to, benzocyclobutene (BCB), an acryl resin, an epoxy resin, a phenolic resin, a polyamide resin, or a polyimide resin. The first planarization layer 161 and the second planarization layer 162 may be formed of the same material.

A hole for electrically connecting the thin film transistor and the light emitting element ED may be formed in the planarization layer 160. The anode electrode AE of the light emitting element ED may be electrically connected to the source/drain electrode 240 of the thin film transistor through the hole.

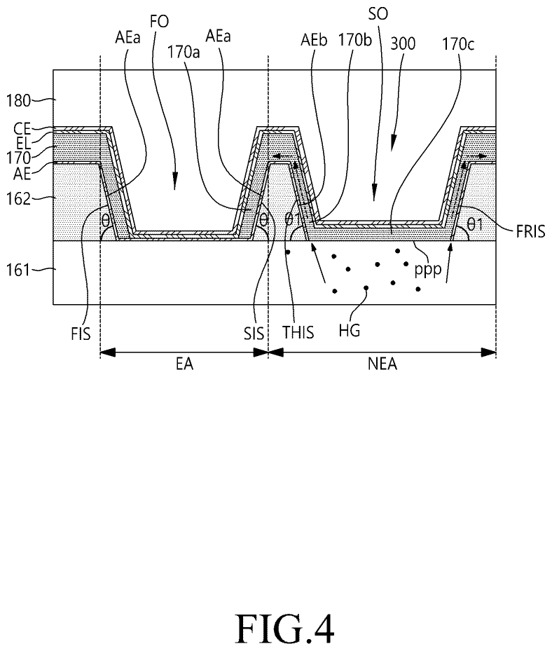

The second planarization layer 162 may be disposed on the first planarization layer 161 and may have a plurality of openings. Hereinafter, a detailed structure of the opening of the second planarization layer 162 is described below with reference to FIG. 4.

The bank layer 170 and the anode electrode AE may be disposed on the second planarization layer 162.

The bank layer 170 may be disposed on the second planarization layer 162 and the anode electrode AE. A spacer 171 may be further disposed in a partial area on the bank layer 170.

The bank layer 170 may have at least one opening area and at least one first trench 300, and a detailed structure thereof is described below with reference to FIG. 4.

When the display device 100 is of a top emission type, the anode electrode AE is a reflective electrode that reflects light and may be disposed using an opaque conductive material.

The light emitting layer EL may be disposed on the anode electrode AE and the bank layer 170.

The light emitting layer EL may include one of a red organic light emitting layer, a green organic light emitting layer, and a blue organic light emitting layer to emit light of a specific color.

In addition to the organic light emitting layer, the light emitting layer EL may further include a hole injection layer, a hole transport layer, an electron injection layer, and an electron transport layer, but is not limited thereto.

A cathode electrode CE may be disposed on the light emitting layer EL.

When the display device 100 is of a top emission type, the cathode electrode CE may be disposed using a transparent conductive material that transmits light.

An encapsulation layer 180 may be disposed on the cathode electrode CE.

Although not illustrated in FIG. 3, the encapsulation layer 180 may include a first encapsulation layer 181, a second encapsulation layer 182 disposed on the first encapsulation layer 181, and a third encapsulation layer 183 disposed on the second encapsulation layer 182.

The encapsulation layer 180 may be formed of a transparent material to transmit light emitted from the light emitting layer EL.

The first encapsulation layer 181 and the third encapsulation layer 183 may be formed of at least one inorganic material among silicon nitride (SiNx), silicon oxide (SiOx), or aluminum oxide (AlyOz), and the second encapsulation layer 182 may be an organic material, e.g., a polymer such as silicon oxycarbide (SiOCz) epoxy, polyimide, polyethylene, acrylate, or the like. However, the disclosure is not necessarily limited thereto.

A layer for providing a touch function may be further disposed on the encapsulation layer 180. Although not illustrated in FIG. 3, a touch insulation layer, a plurality of touch electrodes, and a touch buffer layer may be disposed on the encapsulation layer 180 to provide a touch function. However, the disclosure is not necessarily limited thereto.

Hereinafter, the arrangement structure of the anode electrode AE in the emission area EA and the bank structure in the non-emission area NEA are described in detail with reference to FIGS. 3 and 4.

FIG. 4 is an enlarged view illustrating part A of FIG. 3.

Referring to FIGS. 3 and 4, the subpixel SP or the pixel unit of the display device 100 may include an emission area EA.

The emission area EA may include an area in which the anode electrode AE, the light emitting layer EL, and the cathode electrode CE overlap. The above-described overlapping area may also be referred to as a first emission area (not shown).

The emission area EA may include an area other than an area in which the anode electrode AE, the light emitting layer EL, and the cathode electrode CE overlap. For example, some of the light emitted from the area where the anode electrode AE, the light emitting layer EL, and the cathode electrode CE overlap may be reflected from a first electrode inclined portion AEa of the anode electrode AE and travel in a direction perpendicular to the substrate. Accordingly, the area in which the first electrode inclined portion AEa is disposed may be included in the emission area EA even though the anode electrode AE, the light emitting layer EL, and the cathode electrode CE do not overlap each other in the area. The area in which the first electrode inclined portion AEa is disposed may also be referred to as a second emission area (not shown).

However, the emission area EA may partially include an area in which light is not emitted. For example, light may not be emitted between the area (the first emission area) in which the anode electrode AE, the light emitting layer EL, and the cathode electrode CE overlap each other and the area (the second emission area) in which the first electrode inclined portion AEa is disposed.

A non-emission area NEA may be present outside the emission area EA. The non-emission area NEA is an area in which light is not emitted and may refer to an area other than the emission area EA, and may refer to an area between emission areas EA of the subpixels SP or the pixel units.

In other words, the non-emission area NEA may refer to an area from one end of the emission area EA of one subpixel SP to one end of the emission area of another subpixel.

The second planarization layer 162 may be open in the emission area EA and the non-emission area NEA. The second planarization layer 162 may have a first opening FO in the emission area EA and a second opening SO in the non-emission area NEA. The first opening FO is formed in the second planarization layer 162, and the first opening FO extends through the second planarization layer 162. Similarly, the second opening SO is formed in the second planarization layer 162, and the second opening SO extends through the second planarization layer 162. As the first opening FO and the second opening SO are formed, the second planarization layer 162 may have an inclined surface in each of the emission area EA and the non-emission area NEA. The location of the first opening FO and the second opening SO is different such that the first opening FO does not overlap with the second opening SO from a plan view.

The second planarization layer 162 may have inclined surfaces at two opposite ends (e.g., a first inclined surface FIS and a second inclined surface SIS) of the emission area EA, and the inclined surfaces at two opposite ends (e.g., a first inclined surface FIS and a second inclined surface SIS) of the emission area EA may form an inclination of the same angle θ. To elaborate, the first inclined surface FIS of the second planarization layer 162 has an inclination angle θ with respect to the upper surface US of the first planarization layer 161 (or the upper surface USS of the substrate 120), and the second inclined surface SIS of the second planarization layer 162 has the same inclination angle θ with respect to the upper surface US of the first planarization layer 161 (or the upper surface USS of the substrate 120).

Further, the second planarization layer 162 may have inclined surfaces at two opposite ends (e.g., a third inclined surface THIS and a fourth inclined surface FRIS) of the non-emission area NEA, and the inclined surfaces at two opposite ends (e.g., a third inclined surface THIS and a fourth inclined surface FRIS) of the non-emission area NEA may form an inclination of the same angle θ1. To elaborate, the third inclined surface THIS of the second planarization layer 162 has an inclination angle θ1 with respect to the upper surface US of the first planarization layer 161 (or the upper surface USS of the substrate 120), and the fourth inclined surface FRIS of the second planarization layer 162 has the same inclination angle θ1 with respect to the upper surface US of the first planarization layer 161 (or the upper surface USS of the substrate 120). In some embodiments, inclination angle θ may be identical with inclination angle θ1.

An anode electrode AE may be disposed on the second planarization layer 162. Since the anode electrode AE is disposed to cover the upper surface of the second planarization layer 162, the anode electrode AE may be disposed along the inclined surface of the second planarization layer 162.

The anode electrode AE may have a first electrode inclined portion AEa in the first opening of the second planarization layer 162. The first electrode inclined portion AEa may form an inclination of the same angle as the inclined surface in the first opening of the second planarization layer 162.

Further, the anode electrode AE may have a second electrode inclined portion AEb in the second opening of the second planarization layer 162. The second electrode inclined portion AEb may form an inclination of the same angle as the inclined surface in the second opening of the second planarization layer 162.

The first electrode inclined portion AEa and the second electrode inclined portion AEb may form an inclination of the same angle, and the second electrode inclined portion AEb may form an inclination of an angle larger than that of the first electrode inclined portion AEa, but is not limited thereto. Here, the area in which the first electrode inclined portion AEa is disposed may be the second emission area, but the area in which the second electrode inclined portion AEb is disposed may not be the second emission area. In other words, the first opening of the second planarization layer 162 has at least one emission area including the second emission area, but the second opening may lack at least one emission area including the second emission area.

As shown in FIGS. 3 and 4, the first planarization layer 161 has an upper surface US. The anode electrode AE that is on the second planarization layer 162 contacts the upper surface US of the first planarization layer 161 at the first opening FO.

The bank layer 170 may be disposed to cover the upper surface of the anode electrode AE and the first planarization layer 161.

The bank layer 170 may have an opening area in the emission area EA, may have a first trench 300 in the non-emission area NEA, and the first emission area in which the anode electrode AE, the light emitting layer EL, and the cathode electrode CE overlap may be defined by the area in which the bank layer 170 is open. In other words, the first opening of the second planarization layer 162 includes the first emission area in which the anode electrode AE, the light emitting layer EL, and the cathode electrode CE overlap.

For example, as shown in FIG. 2A, the first trench 300 is disposed between the second electrode inclined portions AEb of the respective anode electrodes AE of two adjacent subpixels. Further, the first trench 300 may be disposed between the respective second emission areas of two adjacent subpixels, i.e., the first electrode inclined portions AEa of the anode electrodes AE.

The bank layer 170 may be disposed along the first electrode inclined portion AEa of the anode electrode AE in the emission area EA, and may have the first bank inclined portion 170a having the same angle as the first electrode inclined portion AEa. The first bank inclined portion 170a may be equally formed at two opposite ends of the emission area EA. One surface of the first bank inclined portion 170a may contact the light emitting layer EL, and the other surface of the first bank inclined portion 170a may contact the first electrode inclined portion AEa.

The bank layer 170 may be disposed along the second electrode inclined portion AEb of the anode electrode AE in the non-emission area NEA, and may have the second bank inclined portion 170b having the same angle as the second electrode inclined portion AEb. The second bank inclined portion 170b may be equally formed at two opposite ends of the non-emission area NEA. One surface of the second bank inclined portion 170b may contact the light emitting layer EL, and the other surface of the second bank inclined portion 170b may contact the second electrode inclined portion AEb.

The bank layer 170 may include a flat area 170c (also referred to as a flat portion 170c) disposed to contact the upper surface of the first planarization layer 161 in an area in which the anode electrode AE of the non-emission area NEA is not disposed. In other words, the second opening of the second planarization layer 162 does not include the first emission area in which the anode electrode AE, the light emitting layer EL, and the cathode electrode CE overlap.

An upper surface of the flat area 170c may be disposed to contact a lower surface of the light emitting layer EL, and the flat area 170c may be connected to the second bank inclined portion 170b. The flat area 170c of the bank layer 170, the light emitting layer EL, and the cathode electrode CE overlap in the second opening of the second planarization layer 162. Here, the flat area 170c of the bank layer 170 may space the planarization layer 160 and the light emitting layer EL apart from each other. In this case, by minimizing the thickness of the flat area 170c, it is possible to minimize the influence of harmful gases HG generated from the planarization layer 160 on the light emitting layer EL, thereby enhancing the reliability of the display device 100.

As is described below, since the flat area 170c is formed using a transflective mask, the flat area 170c may have a height lower than that of the bank layer 170 on the area in which the second planarization layer 162 is disposed. In other words, the height of the bank layer 170 in the area where the first trench 300 is formed may be lower than the height of the bank layer 170 in the area where the second planarization layer 162 is disposed.

In some embodiments, the flat area 170c of the bank layer 170 directly contacts the upper surface US of the first planarization layer 161 at the second opening SO.

The thickness of the first bank inclined portion 170a, i.e., the distance from the surface where the first bank inclined portion 170a contacts the light emitting layer EL to the surface where it contacts the first electrode inclined portion AEa may be larger than the thickness of the second bank inclined portion 170b, i.e., the distance from the surface where the second bank inclined portion 170b contacts the light emitting layer EL to the surface where it contacts the second electrode inclined portion AEb. However, the disclosure is not necessarily limited thereto.

The thickness of the flat area 170c, i.e., the distance from the surface where the flat area 170c contacts the first planarization layer 161 to the surface where it contacts the light emitting layer EL, may be larger than the thickness of the second bank inclined portion 170b. However, the disclosure is not necessarily limited thereto.

In some embodiments, the bank layer 170 includes a first bank inclined portion 170a and a second bank inclined portion 170b adjacent to the first bank inclined portion 170a. In some embodiments, the first bank inclined portion 170a and the second bank inclined portion 170b are on the second planarization layer 162. In some embodiments, the first bank inclined portion 170a and the second bank inclined portion 170b are between the light emitting layer EL and the anode electrode AE.

The light emitting layer EL may be disposed on the bank layer 170.

The cathode electrode CE may be disposed on the light emitting layer EL.

As the bank layer 170 has the first trench 300 in the non-emission area NEA, the height of the bank layer 170 may be larger than height in an area in which the second planarization layer 162 is not disposed in the area in which the second planarization layer 162 is disposed. In other words, the distance from the upper surface of the cathode electrode CE to the upper surface of the first planarization layer 161 in the area in which the first trench 300 is formed may be smaller than the distance in the area in which the first trench 300 is not formed.

Further, the distance from the upper surface of the cathode electrode CE to the upper surface of the first planarization layer 161 may be smaller in the first opening of the second planarization layer 162 than the distance in the area in which the first trench 300 is formed.

An encapsulation layer 180 may be disposed on the bank layer 170.

As described above, since the bank layer 170 has the first trench 300 in the non-emission area NEA, the lengths of the cathode electrode CE and the light emitting layer EL disposed in the non-emission area NEA may be larger than when the bank layer 170 does not have the first trench 300. When the lengths of the cathode electrode CE and the light emitting layer EL become larger, the path of the current flowing through the cathode electrode CE or the light emitting layer EL becomes longer, and thus the resistance may increase. In other words, the resistance of the cathode electrode CE or the light emitting layer EL may increase in the non-emission area NEA or the area between the emission areas EA of the adjacent subpixel SP. Therefore, since the amount of current flowing between adjacent subpixels SP may be reduced, interference that may occur as the distance between the subpixels SP decreases may be reduced.

Further, since the bank layer 170 has a narrow second bank inclined portion 170b in the non-emission area NEA, the path through which harmful gases HG generated from the planarization layer 160 enter the light emitting element ED may be reduced compared to when the second bank inclined portion 170b is not present. Further, the second electrode inclined portion AEb of the anode electrode AE may partially prevent harmful gases HG from entering the light emitting element ED through the bank layer 170, thereby reducing the path through which harmful gases HG enter the light emitting element ED compared to when there is no second electrode inclined portion AEb. Therefore, the reliability of the display device 100 may be enhanced by minimizing the influence of harmful gases HG on the light emitting element ED.

Referring to FIG. 4, the anode electrode AE exposes at least a portion PPP of the upper surface US of the first planarization layer 161. In the exposed portion PPP of the upper surface US of the first planarization layer 161, the anode electrode AE does not cover the exposed portion PPP. In some embodiments, the first opening FO overlaps with an emission area EA (e.g., the emission area EA corresponding to an area where the light emitting element ED emits light) of the display device from a plan view. In some embodiments, the second opening SO overlaps with a non-emission area NEA of the display device from a plan view.

Hereinafter, an example of another structure to which embodiments of the disclosure may be applied is described. However, those described above with reference to FIGS. 2 to 4 are not repeatedly described below.

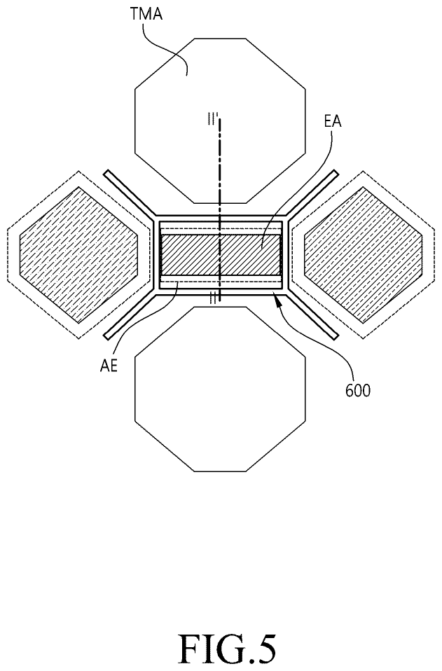

FIG. 5 is a view illustrating another example of a subpixel structure included in a display device according to embodiments of the disclosure.

Referring to FIG. 5, the display device 100 may include a plurality of subpixels SP and a transmissive area TMA on the substrate 120.

The plurality of subpixels SP may include a first subpixel, a second subpixel, and a third subpixel as described above.

The first subpixel, the second subpixel, and the third subpixel may be disposed in a straight line on the same plane. The first subpixel may be disposed between the second subpixel and the third subpixel. However, the disclosure is not necessarily limited thereto.

Although not illustrated in FIG. 5, the display device 100 may include a plurality of wiring units. The plurality of wiring units may include a circuit that provides voltages for driving transistors or light emitting elements ED in the subpixel SP.

The plurality of wiring units may be disposed to cross the subpixel SP. Specifically, the plurality of wiring units may be disposed to cross the line on which the first subpixel, the second subpixel, and the third subpixel are disposed. The plurality of wiring units may be disposed to be spaced apart from each other and may be disposed in a straight line under the second subpixel and the third subpixel. In other words, the line in which the plurality of wiring units are disposed may cross the line in which the first subpixel, the second subpixel, and the third subpixel are disposed.

A transmissive area TMT may be disposed between the plurality of adjacent wiring units. The transmissive area TMA may be defined as an area having higher transparency than the surrounding area, and may be disposed on the front surface of the display panel according to the area in which it is disposed, to be used to increase the transmittance of the display panel, or may be disposed on a sensor for recognizing objects, to be used to provide a path through which light passes.

The transmissive area TMA may be disposed in an area different from the line in which the first subpixel, the second subpixel, and the third subpixel are disposed. A plurality of adjacent wiring units and a first subpixel may be disposed around the transmissive area TMA.

Some layers in the display panel 110 may be omitted from the transmissive area TMA.

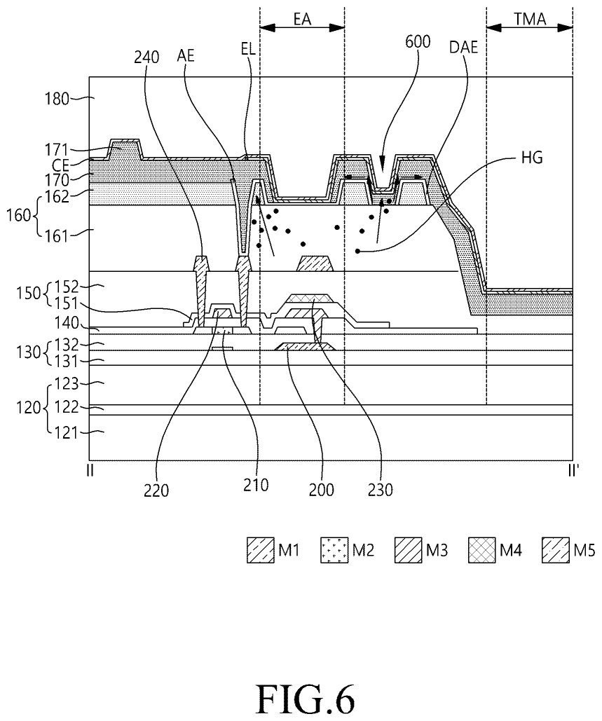

FIG. 6 is a view illustrating an example of a cross-sectional structure of part II-II′ of FIG. 5.

Referring to FIG. 6, the transmissive area TMA may be positioned in an area other than the emission area EA.

The first planarization layer 161, the second planarization layer 162, and the anode electrode AE may not be disposed in an area overlapping the transmissive area TMA.

A dummy anode electrode DAE may be disposed between the emission area EA and the transmissive area TMA. The dummy anode electrode DAE may be disposed on the same layer, i.e., the second planarization layer 162, as the anode electrode AE. The dummy anode electrode DAE may not overlap the light emitting layer EL and the cathode electrode CE. In other words, the dummy anode electrode DAE may be disposed in the non-emission area.

The bank layer 170 may have a second trench 600 between the emission area EA and the transmissive area TMA. The second trench 600 may be formed in the opening of the second planarization layer 162 present between the emission area EA and the transmissive area TMA. As illustrated in FIG. 5, the second trench 600 is disposed between the second electrode inclined portions AEb of the respective anode electrodes AE of two adjacent subpixels, or between the transmissive area TMA and the second electrode inclined portion AEb of the anode electrode AE of at least one subpixel.

As the second trench 600 or the opening of the second planarization layer 162 is formed, the dummy anode electrode DAE may have a third electrode inclined portion between the emission area EA and the transmissive area TMA.

As shown in FIG. 6, the cathode electrode CE includes a trench shape or includes a part of a trench shape (which can be also referred to as a trench shape part). Here, the trench shape part of the cathode electrode CE protrudes towards the first planarization layer 161.

FIG. 6 illustrates a structure in which the bank layer 170 has the second trench 600 and the dummy anode electrode DAE between the emission area EA and the transmissive area TMA, but the bank layer 170 may also have the trench and the dummy anode electrode between the emission areas EA included in the adjacent subpixels SP (not shown). For example, the bank layer 170 may have a trench and a dummy anode electrode between the first subpixel and the second subpixel or between the first subpixel and the third subpixel.

As the lengths of the light emitting layer EL and the cathode electrode CE present between the adjacent subpixels SP when the bank layer 170 has a trench and a dummy anode electrode between adjacent subpixels SP are larger than the lengths of the light emitting layer EL and the cathode electrode CE when no trench is present, the path of the current flowing through the light emitting layer EL and the cathode electrode CE increases, and the resistance in the light emitting layer EL and the cathode electrode CE increases. Therefore, since the amount of current flowing between adjacent subpixels SP may be reduced, interference that may occur as the distance between the subpixels SP decreases may be reduced.

Further, as the second trench 600 is formed, the bank layer 170 may have an inclined area between the emission area EA and the transmissive area TMA.

When the bank layer 170 has an inclined area, the path through which the harmful gases HG generated in the planarization layer 160 flow into the light emitting element ED is reduced compared to when the bank layer 170 does not have an inclined area, and thus the light emitting element ED may be protected from the harmful gases HG, thereby enhancing the reliability of the display device 100.

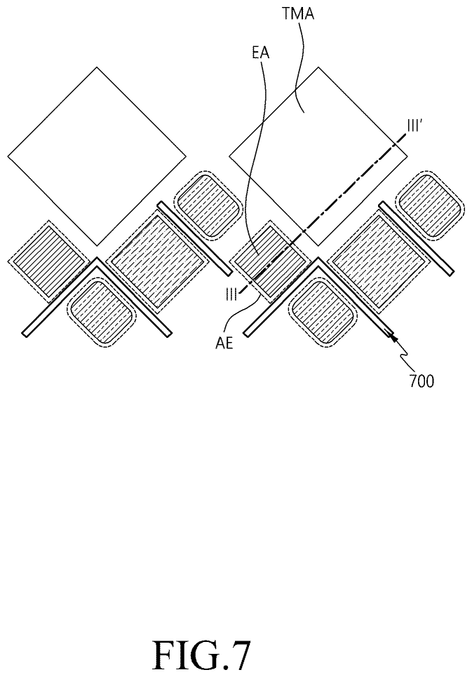

FIG. 7 is a view illustrating another example of a subpixel structure included in a display device according to embodiments of the disclosure.

Referring to FIG. 7, the display device 100 may include a plurality of subpixels SP and a transmissive area TMA on the substrate 120.

As illustrated in FIG. 7, the transmissive area TMA may be formed around a plurality of subpixels SP.

Since light may pass through the transmissive area TMA, the transmissive area TMA may be used as the path through which light enters the sensor for recognizing the user. For example, the display device 100 may further include a configuration of a sensor for recognizing an object under the display panel 110 in the area overlapping the transmissive area TMA. The sensor may generate light for detecting an object, and the light from the sensor is reflected by the object after passing through the transmissive area TMA. The light reflected on the object passes through the transmissive area TMA again and enters the sensor. The sensor may sense the position or size of the object by detecting incoming light.

Further, referring to FIG. 7, the third trench 700 may be disposed between the second electrode inclined portions AEb of the respective anode electrodes AE of two adjacent subpixels, similar to those described above with reference to FIG. 5.

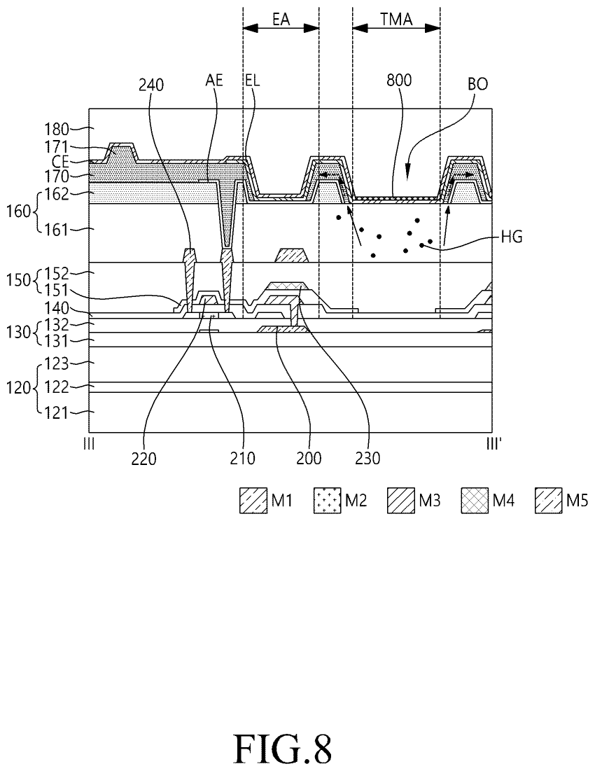

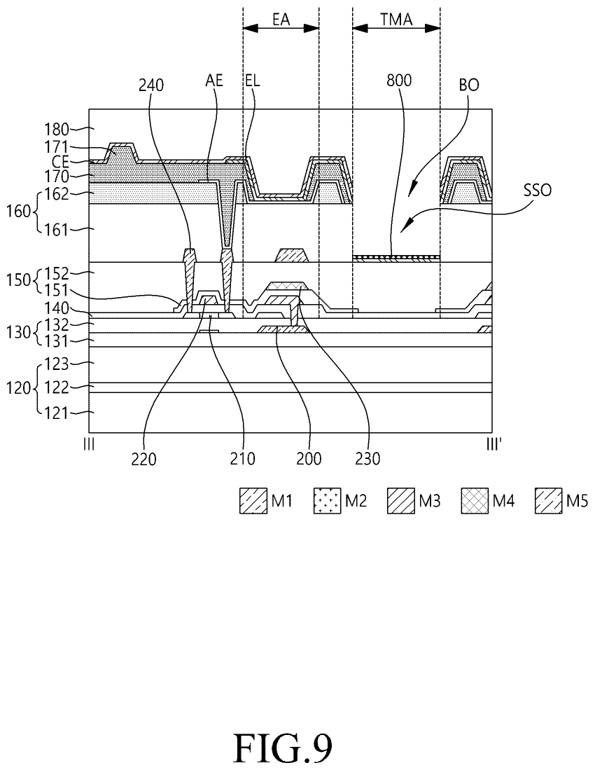

FIG. 8 is a view illustrating an example of a cross-sectional structure of part III-III′ of FIG. 7. FIG. 9 is a view illustrating another example of a cross-sectional structure of part III-III′ of FIG. 7.

Those described above with reference to FIGS. 2 to 6 are not repeatedly described below.

Referring to FIG. 8, the bank layer 170 may have an opening in the transmissive area TMA.

In the transmissive area TMA, the light emitting layer EL may be disposed to cover the first planarization layer 161.

The cathode electrode CE may be disposed on the light emitting layer EL in the transmissive area TMA. In this case, the cathode electrode CE may have a microstructure 800. The microstructure 800 may have a structure in which a portion of the cathode electrode CE is selectively removed. Light may pass through the microstructures 800 of the cathode electrode CE, and the degree to which the cathode electrode CE is removed may be adjusted to adjust the transmittance of light. In some embodiments, the transmissive area TMA overlaps with the microstructure 800 from a plan view as shown in FIGS. 8 and 9.

As the bank layer 170 has an opening in the transmissive area TMA, the bank layer 170 may have an inclined portion between the emission area EA and the transmissive area TMA.

When the bank layer 170 has an inclined portion, the movement path of the harmful gases HG introduced through the bank layer 170 may be reduced compared to when the bank layer 170 does not have an inclined portion. As shown in FIGS. 8 and 9, the bank layer 170 includes a bank opening BO where the bank layer 170 is completely open (e.g., a bank layer 170 is not present in the bank opening BO). Further, since the bank layer 170 is completely open in the transmissive area TMA, the movement path of the harmful gases HG may be further reduced than when the bank layer 170 has a flat area as illustrated in FIGS. 3, 4, and 6. Therefore, it is possible to prevent harmful gases HG from flowing into the light emitting element ED, thereby further enhancing the reliability of the display device 100.

Referring to FIG. 9, the display device 100 may have a structure in which the first planarization layer 161 is further removed from the structure illustrated in FIG. 8.

The bank layer 170 may have an opening (e.g., bank opening BO) in the transmissive area TMA. FIG. 9 shows that the bank layer 170 is not present in the transmissive area TMA due to the bank opening BO. The light emitting layer EL may be disposed on the second insulation layer 152 in the transmissive area TMA, and the cathode electrode CE may be disposed on the light emitting layer EL in the transmissive area TMA.

Although not illustrated in detail in FIG. 9, the light emitting layer EL and the cathode electrode CE disposed in the transmissive area TMA are connected to the light emitting layer EL and the cathode electrode CE outside the transmissive area TMA.

The cathode electrode CE may have a microstructure 800 in the transmissive area TMA. The microstructure 800 may have a structure in which a portion of the cathode electrode CE is selectively removed. Light may pass through the microstructures 800 of the cathode electrode CE, and the degree to which the cathode electrode CE is removed may be adjusted to adjust the transmittance of light.

In some embodiments, in the transmissive area TMA, the light emitting layer EL is disposed on the second interlayer insulation layer 152, and the cathode electrode CE is disposed to have a microstructure 800 on the light emitting layer EL. In some embodiments, the first planarization layer 161 has an opening SSO in the transmissive area TMA. FIG. 9 shows that the first planarization layer 161 is not present in the transmissive area TMA. In the transmissive area TMA, the opening SSO in the first planarization layer overlaps with the bank opening BO from a plan view.

When the first planarization layer 161 is partially removed, the amount of harmful gases introduced through the bank layer 170 is reduced, and thus the harmful gases introduced into the light emitting element ED may be more effectively blocked compared to the structure illustrated in FIG. 8, thereby further enhancing the reliability of the display device 100.

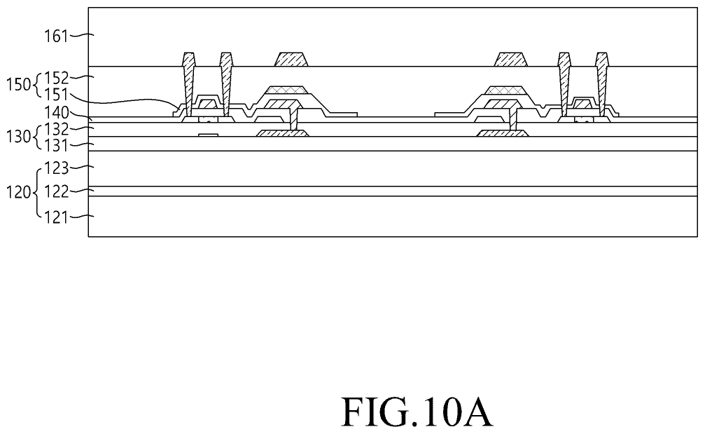

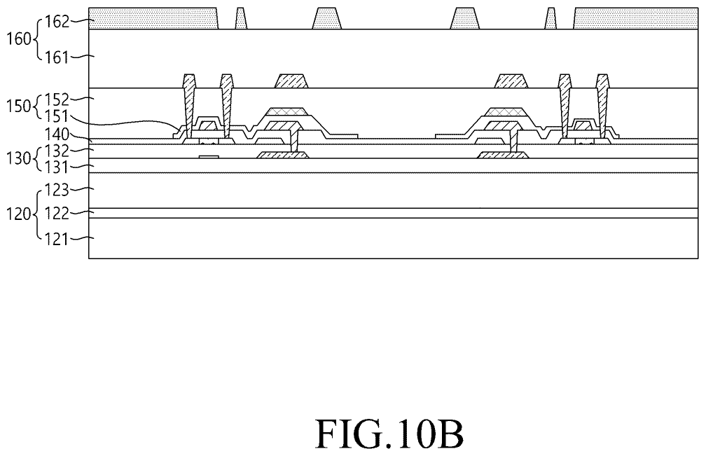

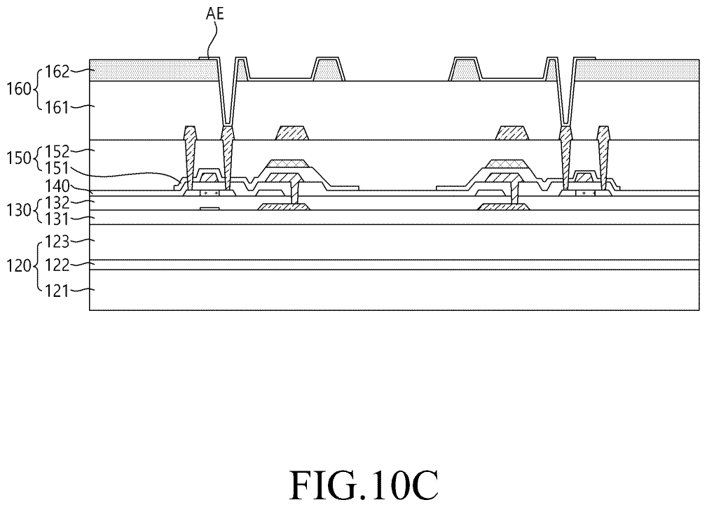

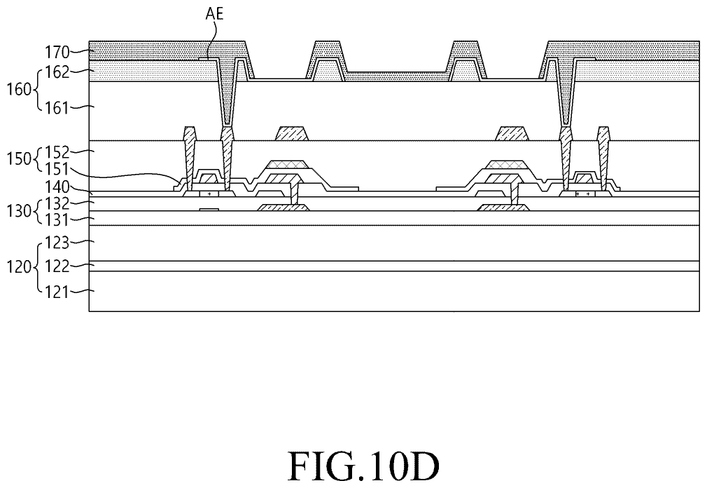

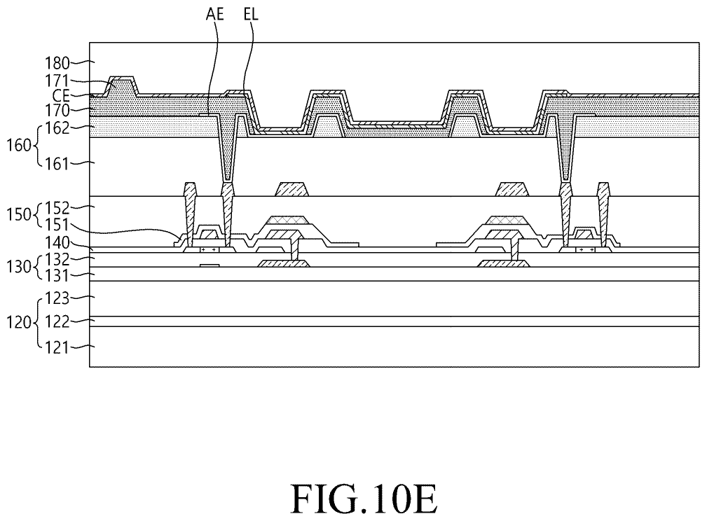

FIG. 10A to 10E are views illustrating an example of a method for manufacturing a display device according to embodiments of the disclosure.

Referring to FIG. 10A, a buffer layer 130, a gate insulation layer 140, and an interlayer insulation layer 150 may be formed on a substrate 120, and a transistor for driving the light emitting element and lines for driving the transistor may be formed.

After the transistor and lines for driving the transistor are formed, a first planarization layer 161 may be formed. An upper surface of the first planarization layer 161 may have a flat surface by the first planarization layer 161.

Referring to FIG. 10B, a second planarization layer 162 may be formed on the first planarization layer 161.

The second planarization layer 162 may be formed of the same material as the first planarization layer 161, and the second planarization layer 162 may be formed to have a plurality of openings. For example, the second planarization layer 162 may be formed to have a first opening in the emission area EA and a second opening in the non-emission area.

When forming the second planarization layer 162, a mask manufactured to allow the non-emission area to be open may be used.

Referring to FIG. 10C, an anode electrode AE may be formed on the second planarization layer 162.

The anode electrode AE may be electrically connected to the source/drain electrode in some areas, and may be formed on the first planarization layer 161 in some areas.

Referring to FIG. 10D, a bank layer 170 may be formed on the second planarization layer 162, the anode electrode AE, and the first planarization layer 161.

The bank layer 170 may be formed to have at least one opening and may be formed to have at least one trench.

A transflective mask may be used when forming the trench in the bank layer 170.

Referring to FIG. 10E, a spacer 171 may be formed on a partial area of the bank layer 170, a light emitting layer EL may be formed on the bank layer 170 and the spacer 171, and a cathode electrode CE may be formed on the light emitting layer EL.

An encapsulation layer 180 may be formed on the cathode electrode CE.

As the second planarization layer 162 has an opening and the bank layer 170 has a trench in the non-emission area, the display device 100 manufactured by the above-described method may reduce the inflow path of harmful gases generated from the planarization layer 160, thereby enhancing the reliability of the display device 100.

Further, as the lengths of the light emitting layer EL and the cathode electrode CE in the area in which the trench is formed are larger than when the trench is not formed, the path of the current formed through the light emitting layer EL or the cathode electrode CE may increase, thereby increasing resistance. Accordingly, current flowing between adjacent subpixels SP may be reduced, thereby reducing interference between subpixels SP.

Embodiments of the disclosure described above are briefly described below.

According to embodiments of the disclosure, there may be provided a display device comprising a substrate where a plurality of subpixels including an emission area and a non-emission area are disposed, a first planarization layer on the substrate, a second planarization layer disposed on the first planarization layer and including a first opening positioned in the emission area and a second opening positioned in the non-emission area, an anode electrode disposed on the second planarization layer, a bank layer disposed in a portion of the emission area and at least a partial area on the first planarization layer and the second planarization layer in the non-emission area, and including at least one trench positioned in the second opening, a light emitting layer disposed on the anode electrode, and a cathode electrode disposed on the light emitting layer.

In the display device according to embodiments of the disclosure, the emission area may include a first emission area and a second emission area, and the anode electrode may have a first electrode inclined portion in the second emission area and a second electrode inclined portion in a portion of the non-emission area.

In the display device according to embodiments of the disclosure, the bank layer may include a first bank inclined portion disposed along the first electrode inclined portion and a second bank inclined portion disposed along the second electrode inclined portion. A thickness of the bank layer in the second bank inclined portion may be different from a thickness of the bank layer in the first bank inclined portion.

In the display device according to embodiments of the disclosure, a thickness of the bank layer in the second bank inclined portion may be smaller than a thickness of the bank layer in the first bank inclined portion.

In the display device according to embodiments of the disclosure, the bank layer may further include a flat area disposed to contact the first planarization layer in an area in which the trench is formed. A thickness of the bank layer in the flat area may be larger than a thickness of the bank layer in the second bank inclined portion.

In the display device according to embodiments of the disclosure, a vertical distance between the cathode electrode and an upper surface of the first planarization layer in an area in which the trench is formed may be larger than a vertical distance between the cathode electrode and the upper surface of the first planarization layer in an area in which the trench is not formed.

In the display device according to embodiments of the disclosure, the first planarization layer and the second planarization layer may be formed of the same material.

In the display device according to embodiments of the disclosure, the first electrode inclined portion and the second electrode inclined portion may have an inclination of the same angle.

According to embodiments of the disclosure, there may be provided a display device comprising a substrate including an emission area and a transmissive area, a plurality of insulation layers on the substrate, a first planarization layer disposed on the plurality of insulation layers, a second planarization layer disposed on the first planarization layer and including a first opening positioned in the emission area and a second opening positioned between the emission area and the transmissive area, an anode electrode disposed on the second planarization layer, a bank layer disposed in a portion of the emission area and at least a partial area on the first planarization layer and the second planarization layer between the emission area and the transmissive area, a light emitting layer disposed on the anode electrode, and a cathode electrode disposed on the light emitting layer.

In the display device according to embodiments of the disclosure, the display device may further comprise a plurality of pixel units emitting light of different colors, and a plurality of wiring units disposed to cross the plurality of pixel units, wherein the plurality of pixel units include a first pixel unit, a second pixel unit, and a third pixel unit. The first pixel unit, the second pixel unit, and the third pixel unit may be disposed in a straight line on the same plane. The first pixel unit may be disposed between the second pixel unit and the third pixel unit.

In the display device according to embodiments of the disclosure, the plurality of wiring units may be disposed on the second pixel unit and the third pixel unit. The transmissive area may be formed between a plurality of adjacent wiring units.

In the display device according to embodiments of the disclosure, the bank layer may have a trench between the first pixel unit and the second pixel unit or between the first pixel unit and the third pixel unit or between the first pixel unit and the transmissive area.

In the display device according to embodiments of the disclosure, the emission area may include a first emission area and a second emission area. The anode electrode may have a first electrode inclined portion in the second emission area and a second electrode inclined portion between the emission area and the transmissive area.

The display device according to embodiments of the disclosure may further comprise a dummy anode electrode disposed on the same layer as the anode electrode and having a third electrode inclined portion disposed on the second planarization layer.

In the display device according to embodiments of the disclosure, the bank layer may have a bank opening in the transmissive area. In the transmissive area, the light emitting layer may be disposed on the first planarization layer, and the cathode electrode may be disposed to have a microstructure on the light emitting layer.

In the display device according to embodiments of the disclosure, the bank layer may have a bank opening in the transmissive area. The first planarization layer may have a structure open in the transmissive area. In the transmissive area, the light emitting layer may be disposed on the plurality of insulation layers, and the cathode electrode may be disposed to have a microstructure on the light emitting layer.

According to embodiments of the disclosure, there may be provided a method for manufacturing a display device, comprising forming a first planarization layer on a substrate, forming a second planarization layer so that a first opening is formed in an emission area and a second opening is formed in a non-emission area on the first planarization layer, forming an anode electrode on a portion of the second planarization layer, and forming a bank layer to have an opening in the emission area and a trench in the non-emission area.

In the method for manufacturing the display device according to embodiments of the disclosure, the bank layer may be formed to have the trench using a transflective mask.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate where a plurality of subpixels including an emission area and a non-emission area are disposed;
a first planarization layer on the substrate;
a second planarization layer on the first planarization layer and including a first opening positioned in the emission area and a second opening positioned in the non-emission area;
an anode electrode on the second planarization layer;
a bank layer disposed in a portion of the emission area and at least a partial area on the first planarization layer and the second planarization layer in the non-emission area, the bank layer including at least one trench;
a light emitting layer on the anode electrode; and
a cathode electrode on the light emitting layer,
wherein the at least one trench overlaps with the second opening from a plan view.

2. The display device of claim 1, wherein the emission area includes a first emission area and a second emission area, and
wherein the anode electrode has a first electrode inclined portion in the second emission area and a second electrode inclined portion in a portion of the non-emission area.

3. The display device of claim 2, wherein the bank layer includes a first bank inclined portion disposed along the first electrode inclined portion and a second bank inclined portion disposed along the second electrode inclined portion, and
wherein a thickness of the bank layer in the second bank inclined portion is different from a thickness of the bank layer in the first bank inclined portion.

4. The display device of claim 3, wherein a thickness of the bank layer in the second bank inclined portion is smaller than a thickness of the bank layer in the first bank inclined portion.

5. The display device of claim 4, wherein the bank layer further includes a flat area disposed to contact the first planarization layer in an area in which the at least one trench is formed, and
wherein a thickness of the bank layer in the flat area is larger than a thickness of the bank layer in the second bank inclined portion.

6. The display device of claim 1, wherein a vertical distance between the cathode electrode and an upper surface of the first planarization layer in an area in which the at least one trench is formed is larger than a vertical distance between the cathode electrode and the upper surface of the first planarization layer in an area in which the at least one trench is not formed.

7. The display device of claim 1, wherein the first planarization layer and the second planarization layer include a same material.

8. The display device of claim 1, wherein the first electrode inclined portion and the second electrode inclined portion have a same inclination angle.

9. A display device, comprising:
a substrate including an emission area and a transmissive area;
a plurality of insulation layers on the substrate;
a first planarization layer on the plurality of insulation layers;
a second planarization layer on the first planarization layer and including a first opening positioned in the emission area and a second opening positioned between the emission area and the transmissive area from a plan view;
an anode electrode on the second planarization layer;
a bank layer in a portion of the emission area and at least a partial area on the first planarization layer and the second planarization layer between the emission area and the transmissive area;
a light emitting layer on the anode electrode; and
a cathode electrode on the light emitting layer.

10. The display device of claim 9, further comprising:
a plurality of pixel units emitting light of different colors; and
a plurality of wiring units disposed to cross the plurality of pixel units,
wherein the plurality of pixel units include a first pixel unit, a second pixel unit, and a third pixel unit,
wherein the first pixel unit, the second pixel unit, and the third pixel unit are disposed in a straight line on a same plane, and
wherein the first pixel unit is disposed between the second pixel unit and the third pixel unit.

11. The display device of claim 10, wherein the plurality of wiring units are disposed on the second pixel unit and the third pixel unit, and
wherein the transmissive area is formed between a plurality of adjacent wiring units.

12. The display device of claim 10, further comprising a trench included in the bank layer, the trench being:
between the first pixel unit and the second pixel unit, or
between the first pixel unit and the third pixel unit, or
between the first pixel unit and the transmissive area.

13. The display device of claim 9, wherein the emission area includes a first emission area and a second emission area, and
wherein the anode electrode has a first electrode inclined portion in the second emission area and a second electrode inclined portion between the emission area and the transmissive area.

14. The display device of claim 9, further comprising a dummy anode electrode on a same layer as the anode electrode and having a third electrode inclined portion disposed on the second planarization layer.

15. The display device of claim 9, wherein the bank layer has a bank opening in the transmissive area, and
wherein in the transmissive area, the light emitting layer is disposed on the first planarization layer, and the cathode electrode is disposed to have a microstructure on the light emitting layer.

16. The display device of claim 9, wherein the bank layer has a bank opening in the transmissive area,
wherein the first planarization layer has a structure open in the transmissive area, and
wherein in the transmissive area, the light emitting layer is disposed on the plurality of insulation layers, and the cathode electrode is disposed to have a microstructure on the light emitting layer.

17. A method for manufacturing a display device, the method comprising:
forming a first planarization layer on a substrate;
forming a second planarization layer on the first planarization layer;
forming a first opening in the second planarization layer in an emission area;
forming a second opening in the second planarization layer in a non-emission area;
forming an anode electrode on a portion of the second planarization layer; and
forming a bank layer to have an opening in the emission area and a trench in the non-emission area.

18. The method of claim 17, wherein the bank layer is formed to have the trench using a transflective mask.

19. A display device, comprising:
a first planarization layer on a substrate, the first planarization layer having a first surface;
a second planarization layer on the first surface of the first planarization layer;
a first opening in the second planarization layer, the first opening extending through the second planarization layer;
a second opening in the second planarization layer, the second opening extending through the second planarization layer;
an anode electrode on the second planarization layer, the anode electrode contacting the first surface of the first planarization layer at the first opening;
a light emitting layer on the second planarization layer;
a cathode electrode on the second planarization layer; and
a light emitting element including the anode electrode, the cathode electrode, and the light emitting layer between the anode electrode and the cathode electrode, the light emitting element overlapping with the first opening from a plan view, the light emitting element configured to emit light,
wherein the first opening does not overlap with the second opening from a plan view.

20. The display device of claim 19, wherein the anode electrode exposes at least a portion of the first surface of the first planarization layer and does not cover the exposed portion of the first surface of the first planarization layer,
wherein the first opening overlaps with an emission area of the display device,
wherein the second opening overlaps with a non-emission area of the display device, and
wherein the emission area of the display device corresponds to an area where the light emitting element emits light.

21. The display device of claim 19, wherein the anode electrode exposes at least a portion of the first surface of the first planarization layer and does not cover the exposed portion of the first surface of the first planarization layer,
wherein the first opening overlaps with an emission area of the display device,
wherein the second opening overlaps with a transmissive area of the display device, and
wherein the emission area of the display device corresponds to an area where the light emitting element emits light.

22. The display device of claim 21, wherein the cathode electrode includes a microstructure,
wherein the microstructure is formed by selectively removing a portion of the cathode electrode to pass light through the microstructure, and
wherein the transmissive area overlaps with the microstructure from a plan view.

23. The display device of claim 19, wherein the cathode electrode is on the first opening and the second opening,
wherein the cathode electrode includes a part of a trench shape at the second opening,
wherein the trench shape of the cathode electrode protrudes towards the first planarization layer.

24. The display device of claim 19, further comprising:
a bank layer including a first bank inclined portion and a second bank inclined portion adjacent to the first bank inclined portion,
wherein the first bank inclined portion and the second bank inclined portion are on the second planarization layer,
wherein the first bank inclined portion and the second bank inclined portion are between the light emitting layer and the anode electrode.

25. The display device of claim 24, wherein the bank layer further includes a flat portion,
wherein the flat portion of the bank layer directly contacts the first surface of the first planarization layer at the second opening.
